(19) United States
(12) Patent Application Publication
(10) Pub. No.: US 2025/0387796 A1
(43) Pub. Date: Dec. 25, 2025

(54) MASK ASSEMBLY

(71) Applicant: Samsung Display Co., LTD., Yongin-si (KR)

(72) Inventors: Sang-Yun LEE, Yongin-si (KR); Seung Min JIN, Yongin-si (KR); YONGHEE HAN, Yongin-si (KR); Byung Jin CHOI, Yongin-si (KR)

(73) Assignee: Samsung Display Co., LTD., Yongin-si (KR)

(21) Appl. No.: 19/057,400

(22) Filed: Feb. 19, 2025

(30) Foreign Application Priority Data
Jun. 25, 2024 (KR) 10-2024-0083171
Jul. 12, 2024 (KR) 10-2024-0092677

(51) Int. Cl. B05B 12/20

(52) U.S. Cl. CPC B05B 12/20

(57) ABSTRACT

A mask assembly includes a support frame, at least two vertical sticks positioned on the support frame and extending in a first direction, at least two first horizontal auxiliary sticks positioned on the support frame and in contact with at least one side of the support frame, extending in a second direction perpendicular to the first direction, and intersecting the at least two vertical sticks in plan view, and at least two second horizontal auxiliary sticks are positioned on the support frame and in contact with at least one side of the support frame, extend in the second direction, and intersect the at least two vertical sticks in plan view. The at least two first horizontal auxiliary sticks and the at least two second horizontal auxiliary sticks contact different sides of the support frame.

### CROSS-REFERENCE TO RELATED APPLICATIONS

This application claims priority to and benefits of Korean Patent Application No. 10-2024-0083171filed at the Korean Intellectual Property Office on Jun. 25, 2024, and Korean Patent Application No. 10-2024-0092677 filed at the Korean Intellectual Property Office on Jul. 12, 2024, under 35 U.S.C. § 119, the entire contents of which are incorporated herein by reference.

BACKGROUND

### 1. Technical Field

Embodiments relate to a mask assembly, and more specifically to a mask assembly that is used in manufacturing a display device.

### 2. Description of the Related Art

Various types of electronic devices are manufactured and sold, and various types of portable electronic devices such as mobile phones, tablets, and laptop PCs are being developed. The electronic devices include light emitting display panels that display images.

A mask may be used for deposition in manufacturing a display device. For example, a mask may be used in a deposition process to form a light emitting layer or the like on a substrate. The light emitting layer may be formed by aligning a substrate on which the light emitting layer is to be formed on a mask on which a predetermined pattern is formed, providing a deposition object such as the light emitting layer to the substrate, and depositing a pattern of a desired shape on the substrate. Recently, a mask containing multiple patterns has been used to deposit a pattern of a desired shape through a single mask.

### SUMMARY

Embodiments provide a mask assembly capable of reducing or minimizing deformation in the mask pattern arrangement structure. Embodiments also provide a mask assembly capable of improving manufacturing margins.

However, embodiments are not limited to those set forth herein. The above and other embodiments will become more apparent to one of ordinary skill in the art to which the disclosure pertains by referencing the detailed description of the disclosure given below.

A mask assembly according to an embodiment includes a support frame, at least two vertical sticks positioned on the support frame and extending in a first direction, at least two first horizontal auxiliary sticks positioned on the support frame and in contact with at least one side of the support frame, extending in a second direction perpendicular to the first direction, and intersecting the at least two vertical sticks in plan view, and at least two second horizontal auxiliary sticks are positioned on the support frame and in contact with at least one side of the support frame, extending in the second direction, and intersecting the at least two vertical sticks in plan view, wherein the at least two first horizontal auxiliary sticks and the at least two second horizontal auxiliary sticks contact different sides of the support frame.

The support frame may include a first region and a second region spaced apart from each other along a boundary extending in the first direction, wherein the at least two first horizontal auxiliary sticks may extend from the first region in the second direction, and the at least two second horizontal auxiliary sticks may be positioned to be shifted from the at least two horizontal auxiliary sticks along the first direction in the second region.

The first region may include at least one first mask pattern defined by the at least two vertical sticks and the at least two first horizontal auxiliary sticks, and the second region may include at least one second mask pattern defined by the vertical sticks and the at least two second horizontal auxiliary sticks.

An arrangement direction of the first mask pattern may be different from an arrangement direction of the second mask pattern.

The at least two first horizontal auxiliary sticks and the at least two second horizontal auxiliary sticks may intersect with different vertical sticks in plan view.

The at least two first horizontal auxiliary sticks and the at least two second horizontal auxiliary sticks may be separated from each other.

At least one end portion of the at least two first horizontal auxiliary sticks and at least one end portion of the at least two second horizontal auxiliary sticks may be welded to the vertical stick.

An end portion of the at least two first horizontal auxiliary sticks and an end portion of the at least two second horizontal auxiliary sticks may be welded to different vertical sticks.

An end portion of the at least two first horizontal auxiliary sticks and an end portion of the at least two second horizontal auxiliary sticks may be welded to a same vertical stick.

The end portion of the at least two first horizontal auxiliary sticks and the end portion of the at least two second horizontal auxiliary sticks may be welded to different regions of the same vertical stick.

The vertical stick to which the end portion of the at least two first horizontal auxiliary sticks and the end portion of the at least two second horizontal auxiliary sticks are welded may have a straight shape.

At least one of the vertical sticks may include a concave portion which is recessed inwardly.

The mask assembly may further include at least one horizontal stick extending in the second direction and connecting two adjacent sides of the support frame.

The mask assembly may include a first region including a first mask pattern defined by the vertical sticks and at least one of the at least two first horizontal auxiliary sticks and the at least two horizontal sticks adjacent to each other.

The mask assembly may include a second region including a second mask pattern defined by the at least two vertical sticks and at least one of the at least two second horizontal auxiliary sticks and the horizontal stick adjacent to each other.

The at least two first horizontal auxiliary sticks and the at least two second horizontal auxiliary sticks may intersect with different vertical sticks.

At least one of the vertical sticks may include a concave portion which is recessed inwardly.

According to an embodiment, the mask assembly may include a support frame, a first frame positioned on the support frame and including a first region including at least one first mask pattern, and a second frame positioned on the support frame and including a second region including at least one second mask pattern, and the first frame and the second frame may be separated from each other.

The first mask pattern included in the first region and the second mask pattern included in the second region may have different arrangement directions.

A mask assembly according to an embodiment may include a support frame, a third frame positioned on the support frame, which includes a first region positioned including at least one first mask pattern and a second region positioned including at least one second mask pattern, and the first region positioned and the second region positioned may have different arrangement forms.

At least one of inner sides of the third frame may include a concave portion which is recessed inwardly.

According to embodiments, deformation in the cell arrangement structure of the mask assembly may be reduced. For example, it is possible to prevent deformation of the mask assembly in a pattern arrangement structure to improve the margin of the mask assembly. For example, in a mask assembly including different mask patterns, deformation of the inner side of the mask assembly according to the arrangement of the different mask patterns may be prevented.

Accordingly, it is possible to form a precise pattern by preventing non-uniform deposition that occurs during the deposition process in case that the mask frame invades the active region forming the display region.

### BRIEF DESCRIPTION OF THE DRAWINGS

FIG. 1 is a schematic exploded perspective view of a display device.

FIG. 2 and FIG. 3 are respectively schematic perspective and exploded perspective views of a mask assembly according to an embodiment.

FIG. 4 and FIG. 5 are respectively schematic plan views schematically showing mask assemblies according to other embodiments.

FIG. 6 is a schematic plan view for explaining reverse correction in a mask assembly according to an embodiment.

FIG. 7 to FIG. 11 are respectively schematic plan views schematically showing mask assemblies according to other embodiments.

FIG. 12 is a schematic diagram illustrating a deposition apparatus having a mask assembly according to an embodiment.

FIG. 13 is a schematic cross-sectional view schematically showing the stacked structure of the display panel.

FIG. 14 is a block diagram of an electronic device.

FIG. 15 is schematic perspective views illustrating application examples of electronic devices.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Bere, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

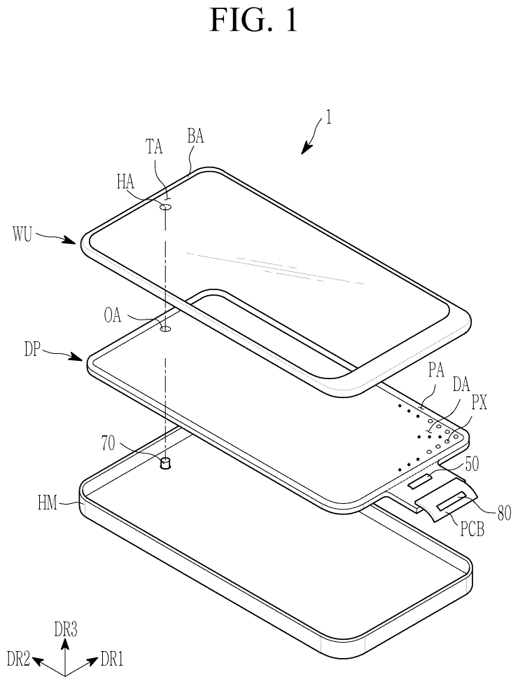

FIG. 1 is a schematic exploded perspective view of a display device.

Referring to FIG. 1, the display device 1 may display an image toward the third direction DR3 intersecting a plane defined by the first direction DR1 and the second direction DR2. The front (or upper) and back (or lower) surfaces of each member may be separated by the third direction DR3. The directions indicated by the first to third directions DR1, DR2, and DR3 are relative concepts and may be converted to other directions.

The display device 1 may display moving images or still images. The display device 1 may be used as the display screen for various products such as mobile phones, smartphones, tablet personal computers (tablet PC), mobile communication terminals, electronic notebooks, e-books, portable multimedia players (PMP), navigation systems, ultramobile PCs (UMPC), as well as televisions, laptops, monitors, billboards, and the Internet of Things (IoT), among other portable electronic devices. For example, the display device 1 according to an embodiment may be used in wearable devices such as smart watches, watch phones, glasses-type displays, and bead mounted displays HMD. For example, the display device 1 according to an embodiment may be used as the dashboard of a car, a center information display CID positioned in the car's center fascia or dashboard, a room mirror display replacing the car's side mirrors, and a display positioned on the back of the front seats for the entertainment of the rear seat passengers. FIG. 1 shows the display device 1 being used as a smart phone for convenience of explanation.

The display device 1 may include a cover window WU, a display panel DP, a component 70, and a housing member HM.

The cover window WU may be disposed on the display panel DP to protect the display panel DP from external shocks, etc. The cover window WU may include a transmission region TA and a blocking region BA. The transmission region TA may be an optically transparent region and may be a region that transmits incident light. The blocking region BA may be a region with relatively low light transmittance compared to the transmission region TA. The blocking region BA may define the shape of the transmission region TA. The blocking region BA may surround the transmission region TA. The blocking region BA may overlap the peripheral region PA of the display panel DP to prevent the peripheral region PA from being viewed from the outside.

The cover window WU may include a hole region HA. The hole region HA may overlap the component 70, which will be described later. The component 70 may operate by receiving external signals provided through the hole region HA. The hole region HA may be positioned in the transmission region TA. The hole region HA may have a circular shape on a plane, and its size or shape may be modified in various ways. The location and number of hole regions (HA) may be changed in various ways.

The display panel DP may be a flat rigid display panel or a flexible display panel. The display panel may be an emissive display panel. For example, the display panel may be an organic light emitting display panel or a quantum dot light emitting display panel. The light emitting layer of the organic light emitting display panel may include an organic light emitting material. The emitting layer of a quantum dot light emitting display panel may include quantum dots, quantum rods, etc. Hereinafter, the display panel will be described as an organic light emitting display panel.

The display panel DP may include a display region DA and a peripheral region PA. The display region DA may be a region where an image is displayed and may correspond to a screen. The peripheral region PA may be a region where an image is not displayed and may surround at least a portion of the display region DA. The display region DA may have an approximately rectangular shape on a plane. The display region DA may have various shapes such as triangles, pentagons, or hexagons, circular shapes, oval shapes, or irregular shapes. Corners of edge portions of the display region DA may have a round shape.

The display region DA may include arranged pixels PX, and an image may be displayed by combining the pixels PX. The pixels PX may be arranged in various forms such as a stripe arrangement, a PenTile® arrangement, or a mosaic arrangement along the first direction DR1 and the second direction DR2 to display an image. The display panel DP may include pixel circuits and signal lines for driving the pixels PX. The display panel DP may be a light emitting display panel including light emitting devices, and each light emitting device may constitute a pixel PX. The display panel DP may be a touch panel including a touch sensor layer capable of detecting touch.

The display panel DP may include an opening region OA penetrating the display panel DP. The opening region OA may overlap the hole region HA of the cover window WU. The opening region OA may be positioned in the display region DA. The opening region OA may be positioned in the upper center of the display region DA. The opening region OA may be positioned in the display region DA in various ways, such as positioned in the upper left or upper right of the display region DA. The opening region OA may have a circular shape on a plane, and its size or shape may be modified in various ways. The location and number of opening regions OA may be changed in various ways.

Some of the pixels PX in the display region DA may be arranged to surround the opening region OA. Accordingly, the image may also be displayed in a region adjacent to the opening region OA.

The display panel DP may extend from the display region DA and include a peripheral region PA where signal lines and a pad portion are positioned. A data driver 50 may be positioned in the peripheral region PA. According to an embodiment, the pad portion of the peripheral region PA may be electrically connected to a printed circuit board PCB including the driving chip 80.

Corresponding to the opening region OA, components 70 for adding various functions to the display device 1 may be positioned. The component 70 may be electrically connected to the display panel DP through a connector or the like. The component 70 may be at least one of a light emitting module, a light sensing module, and a photographing module. For example, the component 70 may include at least one of a light emitting module that outputs infrared rays, a CMOS sensor for detecting infrared rays, and a camera module that photographs an external subject. It is possible to photograph subjects received through the hole region HA and the opening region OA.

The component 70 may be composed of a single module, may include modules, or may be arranged in various sizes and positional relationships.

The housing member HM may be disposed below the display panel DP. The housing member HM may be combined with the cover window WU to form the exterior of the display device 1. The housing member HM may include a material having relatively high rigidity. For example, the housing member HM may include at least one of frames and plates made of glass, plastic, and metal. The display panel DP and the component 70 may be positioned in the internal space of the display device 1 defined by the cover window WU and the housing member HM. The display panel DP may be accommodated within an internal space and protected from external shock.

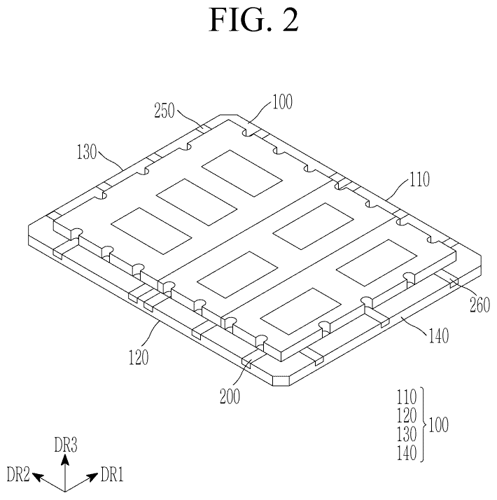

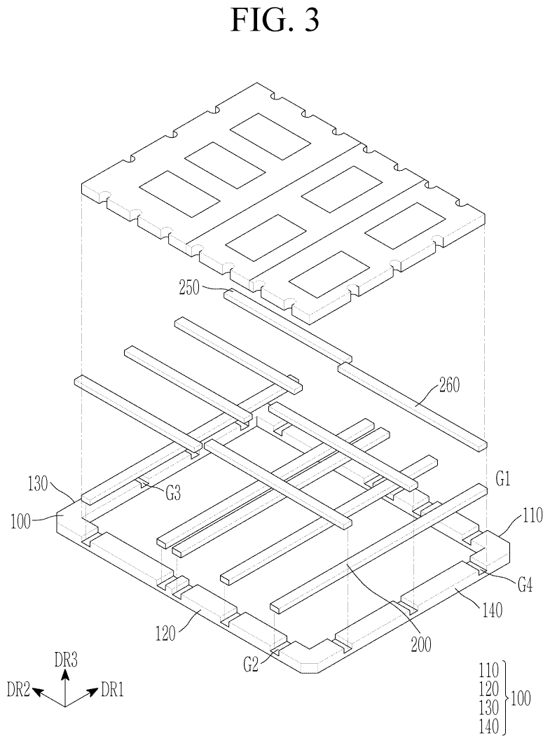

FIG. 2 and FIG. 3 are a schematic perspective view and an exploded schematic perspective view, respectively, of the mask assembly 10 according to an embodiment.

In FIG. 2 and FIG. 3, the mask assembly 10 may include a support frame 100, vertical sticks 200, first horizontal auxiliary sticks 250, and second horizontal auxiliary sticks 260.

The support frame 100 may be substantially rectangular in shape with an opening. The support frame 100 may be defined by four sides 110, 120, 130, and 140. The first side 110 may face the second side 120, and the third side 130 may face the fourth side 140.

First grooves G1 may be formed in the first side 110, and second grooves G2 may be formed in the second side 120. Third grooves G3 may be formed in the third side 130, and fourth grooves G4 may be formed in the fourth side 140. The first grooves G1 and the second grooves G2 may be paired, and the third grooves G3 and the fourth grooves G4 may not be paired. The first grooves G1 and the second grooves G2 may be paired, and the third grooves G3 and the fourth grooves G4 may be paired.

The support frame 100 may be formed of a material having strong rigidity and low deformation so as to affix (or attach) the vertical sticks 200 and the horizontal auxiliary sticks 250 and 260. For example, the support frame 100 may be formed of an alloy such as Invar or stainless steel.

The vertical sticks 200 may be positioned across the opening of the support frame 100 in the first direction DR1 and may be affixed (or attached) to the support frame 100. The longitudinal direction (or extension direction) of the vertical sticks 200 may be parallel to the first direction DR1. End portions (e.g., opposite end portions) of the vertical stick 200 may be inserted into the first groove G1 of the first side 110 and the second groove G2 of the second side 120. End portions (e.g., opposite end portions) of the vertical stick 200 may be inserted into the first groove G1 and the second groove G2 and welded to the first side 110 and the second side 120. The depth of the first groove G1 and the second groove G2 may be substantially the same as the thickness of the vertical stick 200. Accordingly, the vertical stick 200 may be accommodated in the first groove G1 and the second groove G2, so that the upper surface of the vertical stick 200 and the upper surface of the support frame 100 may be substantially flat.

The first horizontal auxiliary sticks 250 and the second horizontal auxiliary sticks 260 may be positioned across the opening of the support frame 100 in the second direction DR2, and may be affixed (or attached) to the support frame 100 and the vertical stick 200. The first horizontal auxiliary sticks 250 and the second horizontal auxiliary sticks 260 may have a longitudinal direction parallel to the second direction DR2. At least one end portion of the first horizontal auxiliary sticks 250 may be inserted into the third groove G3 of the third side 130 of the support frame 100. At least one end portion of the second horizontal auxiliary sticks 260 may be inserted into the fourth groove G4 of the fourth side 140 of the support frame 100. The depth of the third groove G3 and the fourth groove G4 may be substantially the same as the thickness of the first horizontal auxiliary stick 250 and the second horizontal auxiliary stick 260, respectively. Accordingly, the first horizontal auxiliary stick 250 and the second horizontal auxiliary stick 260 may be received in the third groove G3 and the fourth groove G4, respectively, so that the first horizontal auxiliary stick 250 and the second horizontal auxiliary stick 260 and the upper surface of the support frame 100 may be substantially flat.

The vertical sticks 200 may be affixed (or attached) in position below the first horizontal auxiliary stick 250 and the second horizontal auxiliary stick 260. For example, the vertical sticks 200 may be positioned between the support frame 100 and the horizontal auxiliary sticks 250 and 260. In order for the upper surfaces of the first horizontal auxiliary stick 250 and the second horizontal auxiliary stick 260 to be substantially flush with the upper surface of the support frame 100, the depths of the third groove and the fourth groove may be substantially equal to the sum of the thickness of the vertical stick 200 and the thicknesses of the horizontal auxiliary sticks 250 and 260. The thickness of the vertical stick 200 and the first horizontal auxiliary stick 250 and the second horizontal auxiliary stick 260 may be the same or different.

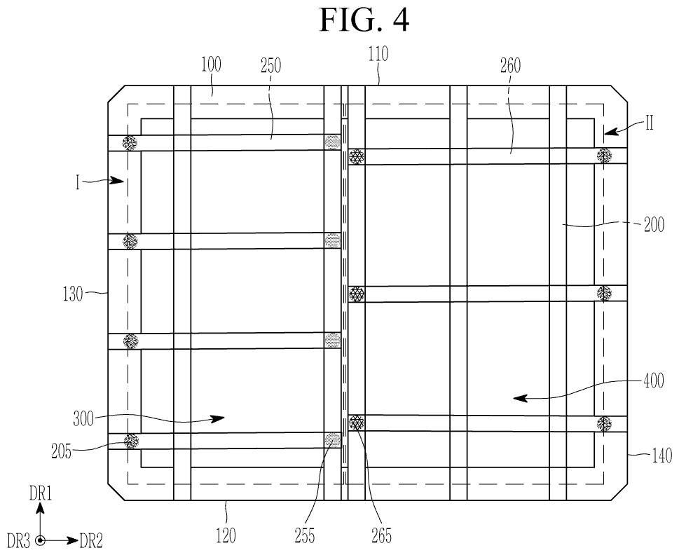

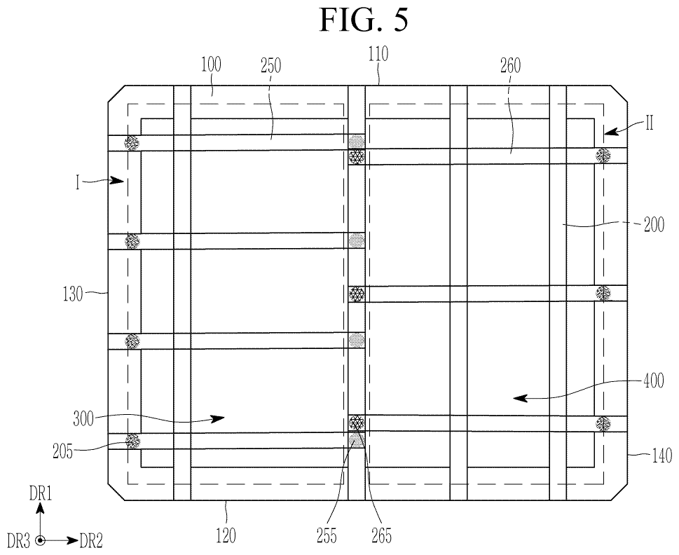

FIGS. 4 and 5 are respectively schematic plan views of the mask assembly 10 according to various embodiments. For example, FIGS. 4 and 5 are respectively plan views of the mask assembly 10 according to various embodiments when viewed from the third direction DR3. In FIGS. 4 and 5, the configuration of the mask stick is omitted for convenience of explanation.

Referring to FIG. 4, at least two vertical sticks 200 may be positioned on the support frame 100 and extend in the first direction DR1. For example, at least two vertical sticks 200 may extend parallel to the first direction DR1 and be affixed (or attached) to the first side 110 and the second side 120 of the support frame 100.

At least two first horizontal auxiliary sticks 250 may be positioned on the support frame 100 in contact with at least one side of the support frame 100 and may extend in the second direction DR2. At least two first horizontal auxiliary sticks 250 may intersect the vertical stick 200. For example, the at least two first horizontal auxiliary sticks 250 may extend parallel to the second direction DR2 and may be affixed (or attached) to the third side 130 and the vertical stick 200 of the support frame 100.

At least two second horizontal auxiliary sticks 260 may be positioned on the support frame 100 in contact with at least one side of the support frame 100 and may extend in the second direction DR2. At least two second horizontal auxiliary sticks 260 may intersect the vertical stick 200. For example, at least two second horizontal auxiliary sticks 260 may extend in parallel with the second direction DR2 and may be secured to the fourth side 140 of the support frame 100 and the vertical stick 200.

The first horizontal auxiliary stick 250 and the second horizontal auxiliary stick 260 may contact different sides of the support frame 100. For example, the first horizontal auxiliary stick 250 may contact the third side 130 of the support frame 100, and the second horizontal auxiliary stick 250 may contact the fourth side 140 of the support frame 100.

At least one end portion of the first horizontal auxiliary stick 250 may be welded to a first welding portion 205 of the third side 130 of the support frame 100. At least one end portion of the first horizontal auxiliary stick 250 may be welded to a second weld portion 255 of the vertical stick 200. The first horizontal auxiliary stick 250 may be affixed (or attached) by welding end portions (e.g., opposite end portions) of the first horizontal auxiliary stick 250 to the third side 130 and the vertical stick 200 of the support frame 100, respectively.

At least one end portion of the second horizontal auxiliary stick 260 may be welded to the first welding portion 205 of the fourth side 140 of the support frame 100. At least one end portion of the second horizontal auxiliary stick 260 may be welded to a third welding portion 265 of the vertical stick 200. The second horizontal auxiliary stick 260 may be affixed (or attached) by welding end portions (e.g., opposite end portions) of the second horizontal auxiliary stick 260 to the fourth side 140 and the vertical stick 200 of the support frame 100, respectively.

The first horizontal auxiliary stick 250 and the second horizontal auxiliary stick 260 may be separated from each other. The first horizontal auxiliary stick 250 and the second horizontal auxiliary stick 260 may be separated (e.g., physically separated) from each other. For example, the first horizontal auxiliary stick 250 and the second horizontal auxiliary stick 260 may be separated (e.g., physically separated) by being welded to different vertical sticks 200. For example, the second welding portion 255 and the third welding portion 265 may be formed at different positions of one vertical stick (or single vertical stick) 200. Accordingly, the first horizontal auxiliary stick 250 and the second horizontal auxiliary stick 260 may be separated (e.g., physically separated). Accordingly, during the formation of the mask assembly 10, the first horizontal auxiliary stick 250 and the second horizontal auxiliary stick 260 may expand and interfere with each other, thereby preventing the sticks 200, 250, and 260 from being deformed.

In an embodiment, the support frame 100 may include a first region I and a second region II that are adjacent to each other along a boundary extending in the first direction DR1.

In an embodiment, the vertical stick 200 and the first horizontal auxiliary stick 250 may intersect each other. For example, the vertical stick 200 and the first horizontal auxiliary stick 250 may intersect while contacting each other. The vertical stick 200 and the first horizontal auxiliary stick 250 may be disposed on the support frame 100 while crossing each other to form a first region I including a first mask pattern 300. For example, the first mask pattern 300 may be defined by dividing the opening of the support frame 100 with vertical sticks 200 and first horizontal auxiliary sticks 250 arranged to cross each other. The first region I may be defined as a region where at least one first mask pattern 300 is formed. FIG. 4 shows three first mask patterns 300 arranged in the vertical direction (e.g., DR1 direction).

In an embodiment, the vertical stick 200 and the second horizontal auxiliary stick 260 may intersect each other. The vertical stick 200 and the second horizontal auxiliary stick 260 may be disposed on the support frame 100 while crossing each other to form a second region II including the second mask pattern 400. For example, the second mask pattern 400 may be defined by dividing the opening of the support frame 100 with vertical sticks 200 and second horizontal auxiliary sticks 260 arranged to cross each other. The second region II may be defined as a region where at least one second mask pattern 400 is formed. FIG. 4 shows four second mask patterns 400 arranged in a 2×2 matrix.

In an embodiment, the first horizontal auxiliary sticks 250 and the second horizontal auxiliary sticks 260 may be positioned to be offset (or shifted) from each other along the first direction DR1. For example, the first horizontal auxiliary sticks 250 may be positioned to be offset (or shifted) from the second horizontal auxiliary sticks 260 along the first direction DR1 in the first region I. For example, the second horizontal auxiliary sticks 260 may be positioned to be offset (or shifted) from the first horizontal auxiliary sticks 250 along the first direction DR1 in the second region II.

In an embodiment, the first horizontal auxiliary stick 250 and the second horizontal auxiliary stick 260 may intersect with different vertical sticks 200. For example, the first horizontal auxiliary stick 250 and the second horizontal auxiliary stick 260 may each come into contact with and intersect the vertical stick 200 disposed in different regions of the support frame 100. Accordingly, the first region I and the second region II may be defined in different regions of the support frame 100, and the regions where the first mask pattern 300 and the second mask pattern 400 are formed may be distinguished (different).

The first mask pattern 300 and the second mask pattern 400 may each correspond to one display panel (or single display panel). The first mask pattern 300 may be formed to correspond to the shape of the display panel by the vertical stick 200 and the first horizontal auxiliary stick 250. The first mask pattern 300 and the second mask pattern 400 may have a rectangular shape, for example.

The first mask pattern 300 and the second mask pattern 400 may have different shapes. For example, the first mask pattern 300 and the second mask pattern 400 may have a rectangular shape and different areas. Accordingly, mask patterns of various shapes may be formed in one mask assembly 10.

The arrangement direction of the first mask pattern 300 may be different from the arrangement direction of the second mask pattern 400. The direction parallel to the long side of the first mask pattern 300 may be different from the direction parallel to the long side of the second mask pattern 400. The long side of the first mask pattern 300 may be parallel to the second direction DR2. The long side of the second mask pattern 300 may be parallel to the first direction DR1. For example, the long side of the first mask pattern 300 and the long side of the second mask pattern 400 may be arranged in directions perpendicular to each other.

The arrangement shape of the first mask pattern 300 in the first region I and the arrangement shape of the second mask pattern 400 in the second region II may be different from each other. For example, in the first region I, the first mask patterns 300 may be arranged so as not to overlap in the vertical direction (e.g., DR1 direction). Two to five, two to four, or three first mask patterns 300 may be arranged in the first region I without overlapping in the vertical direction (e.g., DR1 direction). For example, in the second region II, the second mask patterns 400 may be arranged so as not to overlap each other in the vertical direction (e.g., DR1 direction) and the horizontal direction (e.g., DR2 direction). One to four, one to three, or two second mask patterns 400 may be arranged in the second region II without overlapping in the vertical direction (e.g., DR1 direction). For example, one to four, one to three, or two second mask patterns 400 may be arranged in the second region II without overlapping in the horizontal direction (e.g., DR2 direction).

In an embodiment, at least one end portion of the first horizontal auxiliary stick 250 and at least one end portion of the second horizontal auxiliary stick 260 may be welded to different vertical sticks 200. For example, the first horizontal auxiliary stick 250 and the second horizontal auxiliary stick 260 may be welded to vertical sticks 200 that are separated (e.g., physically separated) from each other. Accordingly, during the formation of forming the mask assembly 10, deformation of the mask patterns 300 and 400 due to different arrangement structures of the first horizontal auxiliary stick 250 and the second horizontal auxiliary stick 260 may be prevented.

Referring to FIG. 5, one end portion of the first horizontal auxiliary stick 250 and one end portion of the second horizontal auxiliary stick 260 may be welded to one vertical stick (or single vertical stick) 200. For example, the second welding portion 255 and the third welding portion 265 may be welded to one vertical stick (or single vertical stick) 200.

One end portion of the first horizontal auxiliary stick 250 and one end portion of the second horizontal auxiliary stick 260 may be welded to different regions of the vertical stick 200. For example, the second welding portion 255 and the third welding portion 265 may be formed in different regions of one vertical stick (or single vertical stick) 200. Accordingly, the first horizontal auxiliary stick 250 and the second horizontal auxiliary stick 260 may be separated (e.g., physically separated). Therefore, in case that manufacturing the mask assembly 10, it is possible to prevent the first horizontal auxiliary stick 250 and the second horizontal auxiliary stick 260 from interacting with each other and being deformed.

The end portions of the first horizontal auxiliary stick 250 and the end portions of the second horizontal auxiliary stick 260, which are welded to the vertical stick 200, may be in a straight form. For example, in case that the first horizontal auxiliary stick 250 and the second horizontal auxiliary stick 260 are welded to different vertical sticks 200, each vertical stick 200 to which the first horizontal auxiliary stick 250 and the second horizontal auxiliary stick 260 are welded may be in a straight form. For example, in case that the first horizontal auxiliary stick 250 and the second horizontal auxiliary stick 260 are welded to one vertical stick (or single vertical stick) 200, the vertical stick 200 with the first horizontal auxiliary stick 250 and the second horizontal auxiliary stick 260 the vertical stick 200 welded together may have a straight shape.

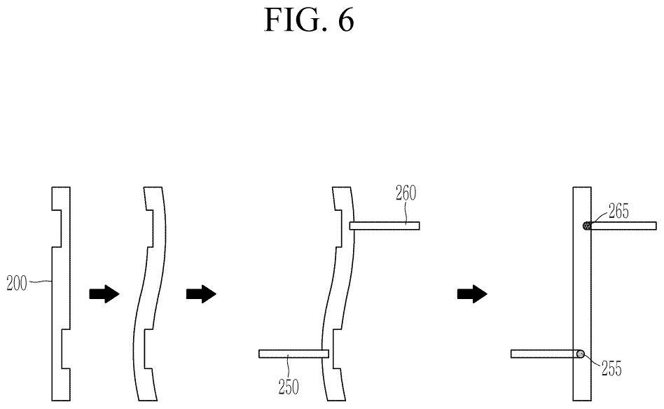

FIG. 6 is a schematic plan view for explaining reverse correction.

Referring to FIG. 6, reverse correction may be performed so that the welded vertical stick 200 may be a straight shape. In FIG. 5, the positions where the welding portions 255 and 265 of the vertical stick 200 are formed are shown as being recessed inward. However, the position where the welding portions 255 and 265 of the vertical stick 200 are formed may be reverse corrected for the vertical stick 200 that is not recessed inwardly.

In case that the first horizontal auxiliary stick 250 and the second horizontal auxiliary stick 260 are welded to the vertical stick 200, the welding portions 255 and 265 of the vertical stick 200 may expand due to the beat generated during welding. Accordingly, deformation of the vertical stick 200 to which the first horizontal auxiliary stick 250 and the second horizontal auxiliary stick 260 are welded may occur. For example, the welding portions 255 and 265 of the vertical stick 200 may be bent in a direction opposite to the longitudinal direction of the horizontal auxiliary sticks 250 and 260.

In order to prevent the deformation, the vertical stick 200 on which at least one welding portion 255 or 265 is formed may be reverse-corrected. The reverse correction may mean bending the vertical stick 200 on which the welding portions 255 and 265 are formed in the longitudinal direction of the horizontal auxiliary sticks 250 and 260. As shown in the direction of the arrow in FIG. 6, in case that the horizontal auxiliary sticks 250 and 260 are welded to the vertical stick 200, the vertical stick 200 and the horizontal auxiliary sticks 250 and 260 may bend in the opposite direction due to expansion. Through reverse correction, the vertical stick 200 of the mask assembly 10 where the vertical stick 200 and the horizontal auxiliary sticks 250 and 260 are welded may maintain a straight shape. Accordingly, it is possible to prevent the mask patterns 300 and 400 of the mask assembly 10 from being deformed.

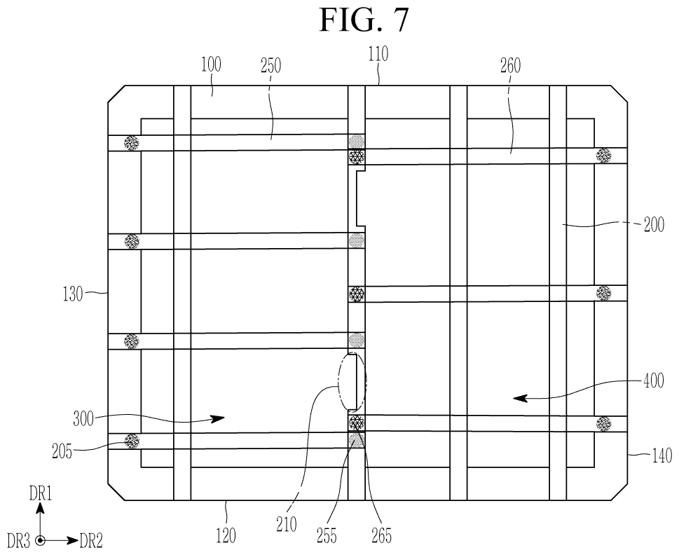

FIG. 7 to FIG. 11 are respectively schematic plan views of the mask assembly 10 according to various embodiments. For example, FIGS. 7 to 11 are respectively schematic plan views of the mask assembly 10 according to various embodiments when viewed from the third direction DR3. In FIGS. 7 to 11, the configuration of the mask stick is omitted for convenience of explanation. The shape, arrangement direction, and arrangement form of the first mask pattern 300 and the second mask pattern 400 of FIGS. 7 to 11 described later may be substantially the same as the shape, arrangement direction, and arrangement form described with reference to FIG. 4.

Referring to FIG. 7, at least one of the vertical sticks 200 may include a concave portion 210 that is recessed inwardly. At least one of the vertical sticks 200 may be recessed inward to form the concave portion 210. For example, the vertical stick 200 in which the first horizontal auxiliary stick 250 and the second horizontal auxiliary stick 260 are welded together may include the concave portion 210 that is recessed inward.

Thermal expansion that occurs during welding the horizontal auxiliary sticks 250 and 260 to the vertical stick 200 may be offset (or shifted) by the concave portion 210. Accordingly, deformation due to thermal expansion that occurs during welding may be prevented. For example, by reverse correcting the vertical stick 200 along with the concave portion, deformation of the vertical stick 200 due to welding may be further prevented. The reverse correction may be the reverse correction described with reference to FIG. 6.

In order to prevent deformation of the vertical stick 200 and the horizontal auxiliary sticks 250 and 260, the concave portion 210 may be formed not only on the vertical stick 200 to which the horizontal auxiliary sticks 250 and 260 are welded, but also on other vertical sticks 200 and horizontal auxiliary sticks 250 and 260. For example, the concave portion 210 may be formed in at least one of the vertical stick 200, the first horizontal auxiliary stick 250, and the second horizontal auxiliary stick 260.

In an embodiment, the mask assembly 10 may further include additional horizontal auxiliary sticks. A third horizontal auxiliary stick may be positioned across the opening of the support frame 100 in the second direction DR2, and at least one end portion of the additional horizontal auxiliary stick may be affixed (or attached) to the support frame 100. At least one end portion of the additional horizontal auxiliary stick may be affixed (or attached) to the vertical stick 200. The third horizontal auxiliary stick may have a longitudinal direction parallel to the second direction DR2. At least one end portion of the third horizontal auxiliary stick may be inserted into at least one of a third groove of the third side 130 and a fourth groove of the fourth side 140 of the support frame 100.

The depth of at least one of the third groove and the fourth groove may be substantially the same as the thickness of the additional horizontal auxiliary stick. Accordingly, at least one end portion of the additional horizontal auxiliary stick may be accommodated in at least one of the third groove and the fourth groove, so that the upper surface of the additional horizontal auxiliary stick and the upper surface of the support frame 100 may become substantially flat.

In an embodiment, the vertical stick 200 and the additional horizontal auxiliary stick may intersect each other. The vertical stick 200 and the additional horizontal auxiliary stick may be disposed on the support frame 100 while crossing each other to form an additional region including an additional mask pattern. For example, the additional mask pattern may be defined by dividing the opening of the support frame 100 with vertical sticks 200 and the additional horizontal auxiliary sticks arranged to cross each other. The additional region may be defined as a region where at least one additional mask pattern is formed.

For example, the additional region may be formed in a portion of the first region I or a portion of the second region II. For example, some of the first mask patterns 300 in the first region I may be provided as additional mask patterns having different shapes or arrangement directions. For example, a region where the shape or arrangement direction of some of the first mask patterns 300 are different may be defined as an additional region. For example, some of the second mask patterns 400 in the second region II may be provided as the additional mask pattern having a different shape or arrangement direction. For example, a region where the shape or arrangement direction of some of the second mask patterns 400 are different may be defined as an additional region.

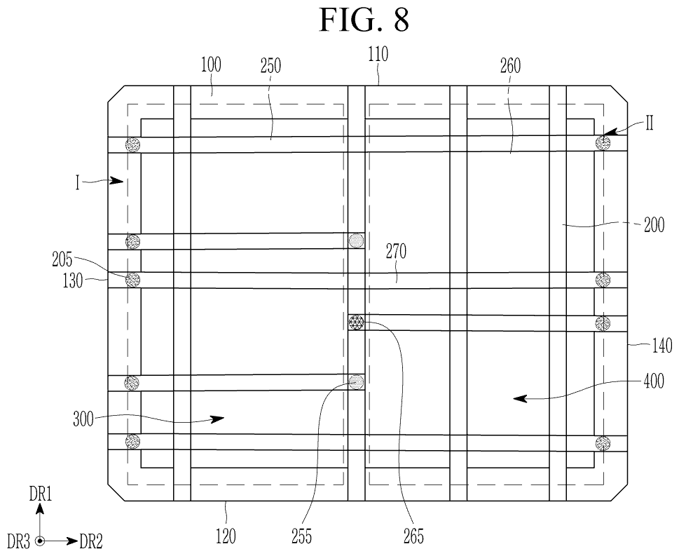

Referring to FIG. 8, the mask assembly 10 may further include at least one horizontal stick 270 connecting two adjacent sides of the support frame 100.

The horizontal stick 270 may be positioned across the opening of the support frame 100 in the second direction DR2, and the horizontal stick 270 may be affixed (or attached) to the support frame 100. The longitudinal direction of the horizontal stick 270 may be parallel to the second direction DR2. The horizontal stick 270 may be inserted into the third groove of the third side 130 and the fourth groove of the fourth side 140 of the support frame 100. The depth of the third groove and the fourth groove may be substantially the same as the thickness of the horizontal stick 270. Accordingly, the horizontal stick 270 may be accommodated in the third groove and the fourth groove, so that the upper surface of the horizontal stick 270 and the upper surface of the support frame 100 may be substantially flat.

The vertical stick 200 and horizontal stick 270 may intersect each other in a plan view. The vertical stick 200 and the horizontal stick 270 may be positioned on the support frame 100 along with the first horizontal auxiliary stick 250 and the second horizontal auxiliary stick 260 while intersecting each other.

A first region I including the first mask pattern 300 may be defined by the vertical stick 200 and at least one of the first horizontal auxiliary stick 250 and the horizontal stick 270 that are adjacent to each other. For example, the first mask pattern 300 may be formed by the vertical stick 200 and two adjacent first horizontal auxiliary sticks 250. For example, the first mask pattern 300 may be formed by the vertical stick 200 and one first horizontal auxiliary stick 250 and horizontal stick 270 that are adjacent to each other. For example, the first mask pattern 300 may be formed by the vertical stick 200 and two adjacent horizontal sticks 270.

The second region II including the second mask pattern 300 may be defined by the vertical stick 200 and at least one of the second horizontal auxiliary sticks 260 and horizontal sticks 270 that are adjacent to each other. For example, the second mask pattern 400 may be formed by the vertical stick 200 and two second horizontal auxiliary sticks 260 that are adjacent to each other. For example, the second mask pattern 400 may be formed by the vertical stick 200 and one second horizontal auxiliary stick 260 and horizontal stick 270 that are adjacent to each other. For example, the second mask pattern 400 may be formed by the vertical stick 200 and two adjacent horizontal sticks 270.

In case that the horizontal stick 270 is formed, the positional relationship between the first horizontal auxiliary stick 250 and the second horizontal auxiliary stick 260 is the same as described above. In case that the horizontal stick 270 is formed, the first horizontal auxiliary stick 250 and the second horizontal auxiliary stick 260 may intersect with different vertical sticks 200.

In case that the horizontal stick 270 is formed, at least one concave portion 210 may be formed on at least one of the vertical stick 200, the first horizontal auxiliary stick 250, the second horizontal auxiliary stick 260, and the horizontal stick 270. Accordingly, deformation that occurs due to welding during manufacturing the mask assembly 10 may be prevented.

The vertical stick 200, the first horizontal auxiliary stick 250, the second horizontal auxiliary stick 260, and the horizontal stick 270 may be formed of metal, for example, an alloy such as Invar or stainless steel.

The vertical stick 200, the first horizontal auxiliary stick 250, the second horizontal auxiliary stick 260, and the horizontal stick 270 may support mask sticks. For example, the mask sticks may be positioned on the vertical stick 200, the first horizontal auxiliary stick 250, the second horizontal auxiliary stick 260, and the horizontal stick 270. The lower surfaces of the mask sticks may contact the upper surfaces of the vertical stick 200, the first horizontal auxiliary stick 250, the second horizontal auxiliary stick 260, and the horizontal stick 270. The mask sticks may be prevented from sagging or deforming by being supported by the vertical stick 200, the first horizontal auxiliary stick 250, the second horizontal auxiliary stick 260, and the horizontal stick 270.

The mask stick may be divided into the first mask pattern 300 in the first region I and the second mask pattern 400 in the second region II by the vertical stick 200, the first horizontal auxiliary stick 250, the second horizontal auxiliary stick 260, and the horizontal stick 270. The mask sticks may be positioned across the opening of the support frame 100 in the first direction DR1 and may be affixed (or attached) to the support frame 100. The mask stick may be affixed (or attached) to the first side 110 and the second side 120 of the support frame 100 through welding while being stretched in the longitudinal direction. A tensile welder may be used to tension and weld the mask stick 150, and end portions (e.g., opposite end portions) of the mask stick may have a structure suitable for clamping for tensioning.

Mask sticks may be combined to form a mask corresponding to one mother substrate (or single mother substrate). Accordingly, the mask stick may be referred to as a split mask. Each of the mask sticks may include mask patterns 300 and 400 corresponding to cells.

For example, each mask pattern 300 and 400 may include through holes corresponding to the patterns of the specific color light emitting layers (for example, red-light emitting layers, green-light emitting layers, or blue-light emitting layers) that will be formed in each cell of the mother substrate. The deposition material forming the light emitting layers may pass through the through holes of the mask stick and may be deposited on each cell of the substrate.

The mask stick may be formed of a metal or alloy, such as Invar or stainless steel. The mask sticks may be fine metal masks FMM.

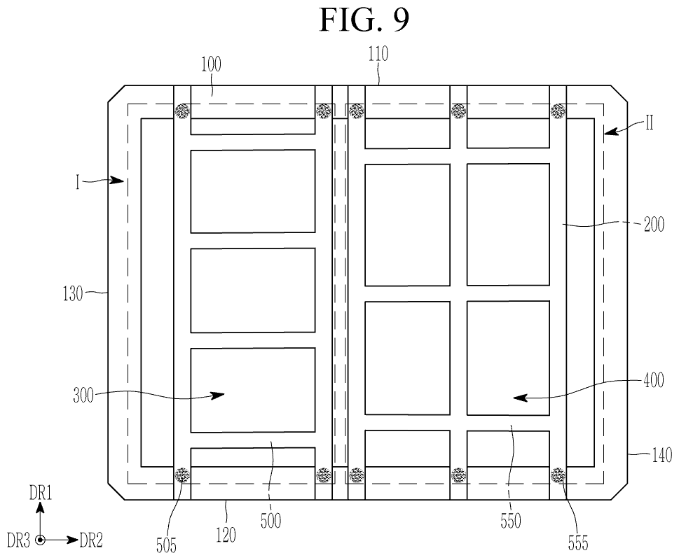

Referring to FIG. 9, the mask assembly 10 may include a first frame 500 including a first region I. The first region I may include at least one first mask pattern 300. For example, the mask assembly 10 may include a second frame 550 including the second region II. The second region II may include at least one second mask pattern 400.

An opening defining the first mask pattern 300 may be formed in the first frame 500, and an opening defining the second mask pattern 400 may be formed in the second frame 550. The first region I may be defined by a first mask pattern 300 formed on the first frame 500, and a second region II may be defined by a second mask pattern 400 formed on the second frame 550.

The first frame 500 and the second frame 550 may each be disposed on the support frame 100. End portions (e.g., opposite end portions) of the first frame 500 may be inserted into the first groove of the first side 110 and the second groove of the second side 120 of the support frame 100, respectively. End portions (e.g., opposite end portions) of the second frame 550 may be inserted into the first groove of the first side 110 and the second groove of the second side 120 of the support frame 100, respectively.

The depth of the first groove and the second groove may be substantially the same as the thickness of the first frame 500 and the second frame 550, respectively. Accordingly, the first frame 500 and the second frame 550 may be accommodated in the first groove and the second groove, respectively, so that the upper surfaces of the first frame 500 and the second frame 550 and the upper surface of the support frame 100 may be substantially flat.

End portions (e.g., opposite end portions) of the first frame 500 may be welded at a fourth welding portion 505 of the first side 110 and a fifth welding portion 555 of the second side 120 of the support frame 100, respectively. End portions (e.g., opposite end portions) of the first frame 500 and the second frame 550 may be welded and affixed (or attached) to the first side 110 and the second side 120 of the support frame 100, respectively.

The first frame 500 and the second frame 550 may be separated (e.g., physically separated). For example, the first frame 500 and the second frame 550 may be positioned in different regions of the support frame 100. Accordingly, during the formation of forming the mask assembly 10, as the first frame 500 and the second frame 550 expand, they may interfere with each other, thereby preventing deformation of the shape of the first mask pattern 300 and the second mask pattern 400.

The arrangement of the first mask patterns 300 disposed in the first region I defined by the first frame 500 and the second mask patterns 400 disposed in the second region II defined by the second frame 550 may be different from each other. For example, the first mask pattern 300 disposed (or included) in the first region I and the second mask pattern 400 disposed (or included) in the second region II may have different arrangement forms. Accordingly, mask patterns 300 and 400 of various arrangement structures may be provided using one mask assembly (or single mask assembly) 10.

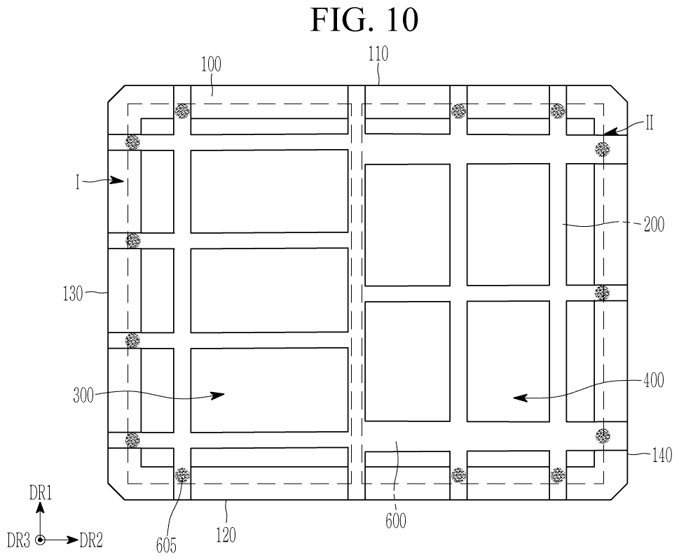

Referring to FIG. 10, the mask assembly 10 may include a third frame 600 including a first region I including at least one first mask pattern 300 and a second region II including at least one second mask pattern 400.

Holes defining the first mask pattern 300 and holes defining the second mask pattern 400 may be formed together in the third frame 600. The first region I may be defined by the first mask pattern 300 formed on the third frame 600, and the second region II may be defined by the second mask pattern 400.

The third frame 600 may be positioned on the support frame 100. End portions (e.g., opposite end portions) of the third frame 600 may be inserted into the first groove of the first side 110 and the second groove of the second side 120 of the support frame 100, respectively. The depths of the first groove and the second groove may each be substantially equal to the thickness of the third frame 600. Accordingly, end portions (e.g., opposite end portions) of the third frame 600 may be inserted into the first groove and the second groove, so that the upper surface of the third frame 600 and the upper surface of the support frame 100 may be substantially flat.

End portions (e.g., opposite end portions) of the third frame 600 may be welded at the sixth welding portion 605 of the first side 110 of the support frame 100. End portions (e.g., opposite end portions) of the third frame 600 may be welded and affixed (or attached) to the first side 110 and the second side 120 of the support frame 100.

The arrangement structures of the first mask patterns 300 included in the first region I and the second mask patterns 400 included in the second region II of the third frame 600 may be different from each other. For example, the first mask pattern 300 included in the first region I and the second mask pattern 400 included in the second region II may have different arrangement forms. Accordingly, the mask patterns 300 and 400 of various arrangement structures may be provided using one mask assembly 10.

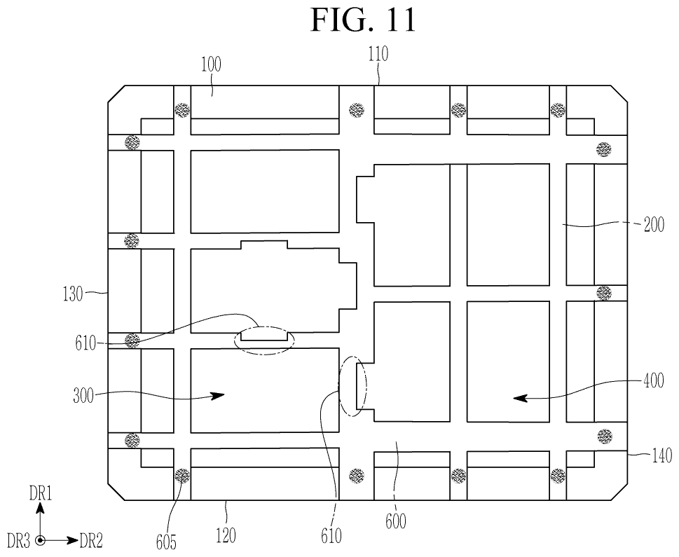

Referring to FIG. 11, at least one of the inner sides of the third frame 600 may include a concave portion 610 that is recessed inwardly. For example, the inner edge portion formed between the first region I and the second region II may include the concave portion 610 that is recessed inwardly. For example, at least one of the inner edge portion between the first mask patterns 300 and the inner edge portion between the second mask patterns 400 may include the concave portion 610 that is recessed inwardly. The concave portion 610 may prevent deformation due to thermal expansion that occurs during the welding of the third frame 600 to the support frame 100.

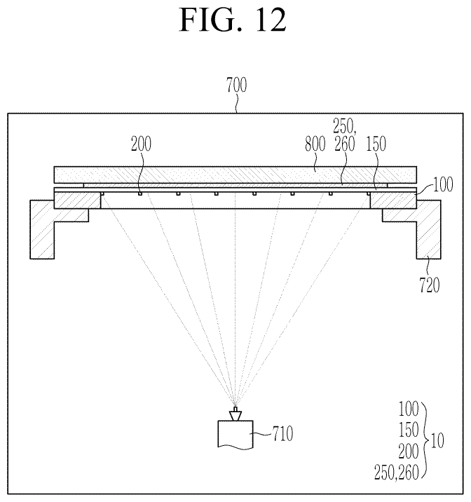

FIG. 12 is a schematic diagram illustrating deposition using the mask assembly 10 according to an embodiment.

Deposition may be performed using a deposition apparatus including a chamber 700, a deposition source 710, and the mask assembly 10. The chamber 700 may form an internal space where a deposition process is performed. A holder 720 may be positioned in the chamber 700, and the support frame 100 of the mask assembly 10 may be detachably affixed (or attached) to the holder 720. The mother substrate 800 may be positioned on the mask assembly 10 to be aligned with the mask assembly 10. The deposition source 710 may store and spray the deposition material to be deposited on the mother substrate 800.

In case that the light emitting layer-forming material evaporates from the deposition source 710 positioned at the lower side of the chamber 700, the light emitting layer-forming material may be deposited onto the mother substrate 800 through the through holes of the mask stick 150, such that the light emitting layers may be formed at the desired positions. The vertical stick 200, the first horizontal auxiliary stick 250, and the second horizontal auxiliary stick 260 of the mask assembly 10 may prevent the light emitting layer-forming material from passing through and dividing the first mask pattern and the second mask pattern. The vertical sticks 200 of the mask assembly 10 may prevent the light emitting layer-forming material from passing through the gap between the mask sticks 150 and being deposited onto the mother substrate 800.

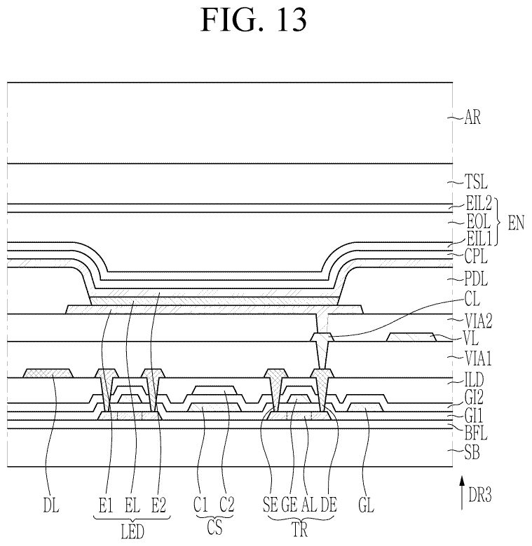

FIG. 13 is a schematic cross-sectional view schematically showing a stacked structure of a display panel according to an embodiment. The display panel may be formed using the mask assembly 10 according to an embodiment.

Cells formed on the mother substrate 800 through the deposition process shown in FIG. 12 may be divided and used as a display panel of a display device. The cross-section shown in FIG. 13 may correspond to approximately one pixel region (or single pixel region).

The display panel may include function layers such as a substrate SB, a transistor TR formed on the substrate SB, and a light emitting diode LED connected to the transistor TR. A light emitting diode LED may correspond to a pixel.

The substrate SB may be made of a material such as glass. The substrate SB may be a flexible substrate including a polymer resin such as polyimide, polyamide, or polyethylene terephthalate.

A buffer layer BFL may be positioned on the substrate SB. The buffer layer BFL may improve the characteristics of the semiconductor layer by blocking impurities from the substrate SB during the formation of forming the semiconductor layer, and may relieve stress on the semiconductor layer by flattening the surface of the substrate SB. The buffer layer BFL may include an inorganic insulating material such as silicon nitride SiNx, silicon oxide SiOₓ, or silicon nitride SiOₓN_{y}, and may be a single layer or multiple layers. The buffer layer BFL may include amorphous silicon Si.

The semiconductor layer AL of the transistor TR may be positioned on the buffer layer BFL. The semiconductor layer AL may include a first semiconductor region, a second semiconductor region, and a channel region between the first and second semiconductor regions. The semiconductor layer AL may include any one of amorphous silicon, polycrystalline silicon, and oxide semiconductor. For example, the semiconductor layer AL may include indium-gallium-zinc oxide IGZO.

A first gate insulating layer GI1 may be positioned on the semiconductor layer AL. The first gate insulating layer GI1 may include an inorganic insulating material such as silicon nitride, silicon oxide, or silicon oxynitride, and may be a single layer or a multilayer.

A first gate conductive layer that includes the gate electrode GE of the transistor TR, the gate line GL, the first electrode C1 of the capacitor CS, etc. may be positioned on the first gate insulating layer GI1. The first gate conductive layer may include molybdenum (Mo), aluminum (Al), copper (Cu), titanium (Ti), etc., and may be a single layer or multiple layers.

A second gate insulating layer GI2 may be positioned on the first gate conductive layer. The second gate insulating layer GI2 may include an inorganic insulating material such as silicon nitride, silicon oxide, or silicon oxynitride, and may be a single layer or a multilayer.

A second gate conductive layer that includes the second electrode C2 of the capacitor CS may be positioned on the second gate insulating layer GI2. The second gate conductive layer may include molybdenum (Mo), aluminum (Al), copper (Cu), titanium (Ti), etc., and may be a single layer or a multilayer.

An interlayer insulating layer ILD may be positioned on the second gate insulating layer GI2 and the second gate conductive layer. The interlayer insulating layer ILD may include an inorganic insulating material such as silicon nitride, silicon oxide, or silicon oxynitride, and may be a single layer or multiple layers.

A first data conductive layer that includes the first electrode SE and second electrode DE of the transistor TR, the data line DL, etc. may be positioned on the interlayer insulating layer ILD. The first electrode SE and the second electrode DE may be respectively connected to the first semiconductor region and the second semiconductor region of the semiconductor layer AL through contact holes of the insulating layers GI1, GI2, and ILD. One of the first electrode SE and the second electrode DE may be a source electrode and the other may be a drain electrode. The first data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), etc., and may be a single layer or multiple layers.

A first planarization layer VIA1 may be positioned on the first data conductive layer. The first planarization layer VIA1 may be an organic insulating layer. For example, the first planarization layer VIA1 may include organic insulating materials such as general-purpose polymers like polymethyl methacrylate and polystyrene, polymer derivatives containing phenolic groups, acrylic polymers, imide polymers, polyimides, and siloxane-based polymers.

A second data conductive layer that includes a voltage line VL, a connection line CL, etc. may be positioned on the first planarization layer VIA1. A second data conductive layer that includes a voltage line VL, a connection line CL, etc. may be positioned. The voltage line VL may transmit voltages such as driving voltage, common voltage, initialization voltage, and reference voltage. The connection line CL may be connected to the second electrode DE of the transistor TR through a contact hole in the first planarization layer VIA1. The second data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), etc., and may be a single layer or multiple layers.

A second planarization layer VIA2 may be positioned on the second data conductive layer. The second planarization layer VIA2 may be an organic insulating layer. For example, the second planarization layer VIA2 may include organic insulating materials such as general-purpose polymers like polymethyl methacrylate, polystyrene, polymer derivatives containing phenolic groups, acrylic polymers, imide polymers, polyimides, and siloxane polymers.

The first electrode E1 of the light emitting diode LED may be positioned on the second planarization layer VIA2. The first electrode E1 may be a pixel electrode. The first electrode E1 may be connected to the connection line CL through a contact hole in the second planarization layer VIA2. Accordingly, the first electrode E1 may be electrically connected to the second electrode DE of the transistor TR and may receive a data signal that controls the brightness of the light emitting diode. The transistor TR to which the first electrode E1 is connected may be a driving transistor or a transistor electrically connected to the driving transistor. The first electrode E1 may be formed of a reflective conductive material or a semi-transparent conductive material, or may be formed of a transparent conductive material. The first electrode E1 may include a transparent conductive material such as indium tin oxide IZO. The first electrode E1 may include a metal or metal alloy such as lithium (Li), calcium (Ca), aluminum (Al), silver (Ag), magnesium (Mg), or gold (Au).

A pixel defining layer PDL, which is an organic insulating layer, may be positioned on the second planarization layer VIA2. The pixel defining layer PDL may be a partition and may have an opening that overlaps the first electrode E1.

The light emitting layer EL of the light emitting diode LED may be positioned on the first electrode E1. In addition to the light emitting layer EL, at least one of a hole injection layer, a hole transport layer, an electron transport layer, and an electron injection layer may be positioned on the first electrode E1. The mask assembly 10 described above may be used to deposit the light emitting layer EL.

The second electrode E2 of the light emitting diode LED may be positioned on the light emitting layer EL. The second electrode E2 may be a common electrode. The second electrode E2 provides light transparency by forming a thin layer of metal or metal alloy with a low work function, such as calcium (Ca), barium (Ba), magnesium (Mg), aluminum (Al), and silver (Ag). The second electrode E2 may include a transparent conductive oxide such as indium tin oxide ITO or indium zinc oxide IZO.

The first electrode E1, the light emitting layer EL, and the second electrode E2 of each pixel form a light emitting diode LED such as an organic light emitting diode. The first electrode E1 may be an anode of a light emitting diode, and the second electrode E2 may be a cathode of a light emitting diode.

A capping layer CPL may be positioned on the second electrode E2. The capping layer CPL may increase light efficiency by adjusting the refractive index. The capping layer CPL may be positioned to cover (e.g., entirely cover) the second electrode E2. The capping layer CPL may include an organic insulating material or an inorganic insulating material.

An encapsulation layer EN may be positioned on the capping layer CPL. The encapsulation layer EN may seal the light emitting diode LED and prevent moisture or oxygen from penetrating from the outside. The encapsulation layer EN may be a thin-film encapsulation layer including one or more inorganic layers EIL1 and EIL2 and one or more organic layers EOL.

A touch sensor layer TSL including touch electrodes may be positioned on the encapsulation layer EN. The touch electrodes may have a mesh shape with openings that overlap the light emitting diode LED. An anti-reflection layer AR may be positioned on the touch sensor layer TSL to reduce external light reflection.

A cover window may be positioned on the anti-reflection layer AR to protect the entire front of the display panel.

A protective film to protect the display panel may be positioned under the substrate SB. A functional sheet including at least one of a cushion layer, a beat dissipation sheet, a light blocking sheet, a waterproof tape, and an electromagnetic shielding layer may be positioned under the protective film.

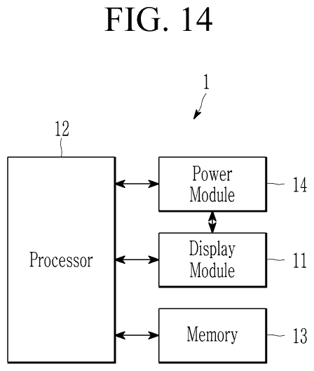

FIG. 14 is a block diagram of an electronic device according to an embodiment. Referring to FIG. 14, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for operations of the processor 12 or the display module 11. When the processor 12 executes an application stored in the memory 13, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 1.

At least one of components of the electronic device 11 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 11 that are not part of the display device.

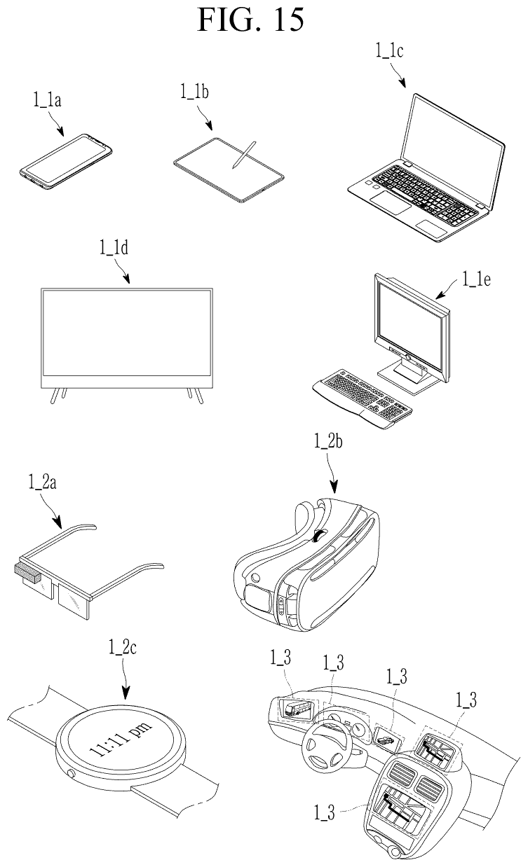

FIG. 15 shows schematic diagrams of electronic devices according to various embodiments.

Referring to FIG. 15, various electronic devices with the display device according to the embodiments may include not only image display electronic devices such as smartphones 1_1a, tablet PCs 1_1b, laptops 1_1c, TVs 1_1d, desktop monitors 1_1e, but also wearable electronic devices with display modules such as smart glasses 1_2a, bead-mounted displays 1_2b, smart watches 1_2c, as well as automotive electronic devices with display modules 1_3 such as those placed on car dashboards, center fascias, CID (Center Information Display), room mirror displays, and so on.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A mask assembly comprising:
a support frame;
at least two vertical sticks positioned on the support frame and extending in a first direction;
at least two first horizontal auxiliary sticks positioned on the support frame and in contact with at least one side of the support frame, extending in a second direction perpendicular to the first direction, and intersecting the at least two vertical sticks in plan view, and
at least two second horizontal auxiliary sticks are positioned on the support frame and in contact with at least one side of the support frame, extending in the second direction, and intersecting the at least two vertical sticks in plan view,
wherein the at least two first horizontal auxiliary sticks and the at least two second horizontal auxiliary sticks contact different sides of the support frame.

2. The mask assembly of claim 1, wherein
the support frame includes a first region and a second region spaced apart from each other along a boundary extending in the first direction,
the at least two first horizontal auxiliary sticks extend from the first region in the second direction, and
the at least two second horizontal auxiliary sticks are positioned to be shifted from the first horizontal auxiliary sticks along the first direction in the second region.

3. The mask assembly of claim 2, wherein
the first region includes at least one first mask pattern defined by the at least two vertical sticks and the at least two first horizontal auxiliary sticks, and
the second region includes at least one second mask pattern defined by the at least two vertical sticks and the at least two second horizontal auxiliary sticks.

4. The mask assembly of claim 3, wherein
an arrangement direction of the first mask pattern is different from an arrangement direction of the second mask pattern.

5. The mask assembly of claim 1, wherein
the at least two first horizontal auxiliary sticks and the at least two second horizontal auxiliary sticks intersect with different vertical sticks in plan view.

6. The mask assembly of claim 1, wherein
the at least two first horizontal auxiliary sticks and the at least two second horizontal auxiliary sticks are separated from each other.

7. The mask assembly of claim 1, wherein
at least one end portion of the at least two first horizontal auxiliary sticks and at least one end portion of the at least two second horizontal auxiliary sticks are welded to the at least two vertical sticks.

8. The mask assembly of claim 7, wherein
an end portion of the at least two first horizontal auxiliary sticks and an end portion of the at least two second horizontal auxiliary sticks are welded to different vertical sticks.

9. The mask assembly of claim 7, wherein
an end portion of the at least two first horizontal auxiliary sticks and an end portion of the at least two second horizontal auxiliary sticks are welded to a same vertical stick.

10. The mask assembly of claim 9, wherein
the end portion of the at least two first horizontal auxiliary sticks and the end portion of the at least two second horizontal auxiliary sticks are welded to different regions of the same vertical stick.

11. The mask assembly of claim 9, wherein
the same vertical stick to which the end portion of the at least two first horizontal auxiliary sticks and the end portion of the at least two second horizontal auxiliary sticks are welded has a straight shape.

12. The mask assembly of claim 1, wherein
at least one of the at least two vertical sticks includes a concave portion which is recessed inwardly.

13. The mask assembly of claim 1, wherein
the mask assembly further includes at least one horizontal stick extending in the second direction and connecting two adjacent sides of the support frame.

14. The mask assembly of claim 13, wherein
the mask assembly includes:
a first region including a first mask pattern defined by the at least two vertical sticks and at least one of the at least two first horizontal auxiliary sticks and the at least two second horizontal auxiliary sticks adjacent to each other, and
a second region including a second mask pattern defined by the at least two vertical sticks and at least one of the at least two second horizontal auxiliary sticks and the horizontal stick adjacent to each other.

15. The mask assembly of claim 13, wherein
the at least two first horizontal auxiliary sticks and the at least two second horizontal auxiliary sticks intersect with different vertical sticks in plan view.

16. The mask assembly of claim 13, wherein
at least one of the at least two vertical sticks includes a concave portion which is recessed inwardly.

17. A mask assembly comprising:
a support frame;
a first frame positioned on the support frame and including a first region including at least one first mask pattern; and
a second frame positioned on the support frame and including a second region including at least one second mask pattern,
wherein the first frame and the second frame are separated from each other.

18. The mask assembly of claim 17, wherein
the first mask pattern included in the first region and the second mask pattern included in the second region have different arrangement directions.

19. A mask assembly comprising:
a support frame; and
a third frame positioned on the support frame and including a first region including at least one first mask pattern and a second region including at least one second mask pattern;
wherein the first region and the second region have different arrangement forms.

20. The mask assembly of claim 19, wherein
at least one of inner sides of the third frame includes a concave portion which is recessed inwardly.
